(19) United States
(12) Patent Application Publication
(10) Pub. No.: US 2026/0316182 A1
(43) Pub. Date: Oct. 15, 2026

(54) SYSTEMS AND METHODS FOR SUBSTRATE LASER ANNEALING

(71) Applicant: Applied Materials, Inc., Santa Clara, CA (US)

(72) Inventors: Kenichi OHNO, Santa Clara, CA (US); Samuel C. HOWELLS, Portland, OR (US); Siddhant PANDEY, Beaverton, OR (US); Jeffrey P. HEBB, Los Gatos, CA (US); Lara HAWRYLCHAK, Mansfield, TN (US); Chaitanya Anjaneyalu PRASAD, San Jose, CA (US); Nicholas QUANSTROM, Mountain View, CA (US); Nila Mohan THAZHE MECHERI, Sunnyvale, CA (US); Francis Kanyiri MUNGAI, Fremont, CA (US); Andy LO, San Jose, CA (US); Shankar MUTHUKRISHNAN, Los Gatos, CA (US); Mehdi VAEZ-IRAVANI, Los Gatos, CA (US); Patrick C. GENIS, Capitola, CA (US)

(21) Appl. No.: 19/643,773

(22) Filed: Apr. 9, 2026

Related U.S. Application Data
(60) Provisional application No. 63/787,221, filed on Apr. 11, 2025.

(51) Int. Cl. B23K 26/082; B23K 26/352; B23K 101/40; H10P 34/42

(52) U.S. Cl. CPC B23K 26/082; B23K 26/352; H10P 34/42; B23K 2101/40

(57) ABSTRACT

A substrate processing chamber is provided. The substrate processing chamber including a substrate support, a radiation module, a support system, and a window. The substrate support is disposed in a processing volume of the processing chamber. The radiation module is configured to generate and emit a beam of radiation including a wavelength within a range of about 750 nanometers (nm) to about 3000 nm. The support system is configured to support a radiation emitting end portion of the radiation module such that the beam of radiation is emitted at an incidence angle towards the substrate support, wherein the incidence angle of incidence is in a range of about 15° to about 70° from a vertical axis and move the radiation emitting end portion to scan an upper surface of a substrate with the beam of radiation. The window positioned between the radiation module and the substrate support.

### CROSS-REFERENCE TO RELATED APPLICATIONS

This application claims the benefit of U.S. Provisional Application No. 63/787,221, filed Apr. 11, 2025, which is incorporated by reference herein in its entirety.

### BACKGROUND

Some embodiments disclosed herein generally relate to semiconductor substrate processing, and more particularly to systems and methods for annealing a substrate in a substrate processing chamber.

Substrates, such as semiconductor substrates, are processed for a wide variety of applications, including the fabrication of integrated devices and microdevices. Generally speaking, some of the processing operations performed on a such a substrate include layering (or material deposition), patterning, doping, and heat treatments. Heat treatments are operations in which the substrate is heated and cooled to achieve specific results. During heat treatment, no additional material is added to or removed from the substrate. Heat treatments, such as rapid thermal processing or annealing, typically involve providing a relatively large amount of thermal energy (high temperatures) to the substrate in a short amount of time, and thereafter rapidly cooling the substrate to terminate the thermal process.

### SUMMARY

In some embodiments, a substrate processing chamber is provided. The substrate processing chamber includes a substrate support, a radiation module, a support system, and a window. The substrate support is disposed in a processing volume of the processing chamber. The radiation module is configured to generate and emit a beam of radiation including a wavelength within a range of about 750 nanometers (nm) to about 3000 nm. The support system is configured to support a radiation emitting end portion of the radiation module such that the beam of radiation is emitted at an incidence angle towards the substrate support, wherein the incidence angle of incidence is in a range of about 15° to about 70° from a vertical axis and move the radiation emitting end portion to scan an upper surface of a substrate with the beam of radiation. The window is positioned between the radiation module and the substrate support.

In some embodiments, a laser annealing system for annealing a substrate is provided. The laser annealing system includes a radiation module and a support system. The radiation module is configured to generate and emit a beam of radiation towards the substrate, the beam of radiation including a wavelength within a range of about 750 nanometers (nm) to about 3000 nm. The support system is configured to support a radiation emitting end portion of the radiation module such that the beam of radiation is emitted at an incidence angle that is in a range of about 15° to about 70° from a vertical axis and move the radiation emitting end portion to scan an upper surface of the substrate with the beam of radiation

In some embodiments, a method of annealing a substrate is provided. The method includes exposing the substrate to a beam of radiation generated by a radiation module and moving the radiation module to traverse an upper surface of a substrate with the beam of radiation to anneal the upper surface of the substrate. The beam of radiation includes a wavelength within a range of about 750 nanometers (nm) to about 3000 nm and an incidence angle that is in a range of about 15° to about 70° from a vertical axis.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the present disclosure and are therefore not to be considered limiting of its scope, as the present disclosure may admit to other equally effective embodiments.

FIG. 1 is a schematic side view of processing system for thermally processing a substrate, according to one or more embodiments.

FIG. 2A is a schematic isometric view of the laser annealing apparatus of the processing system of FIG. 1, according to one or more embodiments.

FIG. 2B is a schematic side cross-sectional view of a portion of the laser annealing apparatus of the processing system of FIG. 1, according to one or more embodiments.

FIG. 2C is a schematic side cross-sectional view of a portion of the laser annealing apparatus of the processing system of FIG. 1, according to one or more embodiments.

FIG. 2D is a schematic side cross-sectional view of a portion of the laser annealing apparatus of the processing system of FIG. 1, according to one or more embodiments.

FIG. 3 is a schematic top view of a substrate during thermal processing, according to one or more embodiments.

FIG. 4 illustrates a method for processing a substrate, according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

A substrate, such as a semiconductor substrate, may be subjected to a number of processing operations. Such processing operations may include a heat treatment or “annealing” process whereby the substrate (and any layers or features formed thereon) may be heated and cooled at a controlled rate. In some cases, an annealing process may be performed by use of a laser that is configured to increase a temperature of the substrate in a relatively small, defined area. However, such laser annealing processes suffer from poor performance due to the different reflectivity (or absorption) properties of different materials, layers, features on a substrate.

Accordingly, embodiments disclosed herein include systems and methods for performing a laser annealing process on a semiconductor substrate (or layers deposited thereon) that may provide a more uniform temperature rise across the substrate, despite the presence of different materials. For instance, in some embodiments, the systems and methods may employ a laser that is oriented at a non-zero angle. Similarly, in some embodiments the systems and methods may employ a laser that outputs light in a wavelength in a defined range in order to overcome the differences in reflectivity (or absorption) of the different materials that may be present on the substrate. Thus, by use of the embodiments disclosed herein, a laser annealing process may provide a more uniform and repeatable result for a variety of substrates.

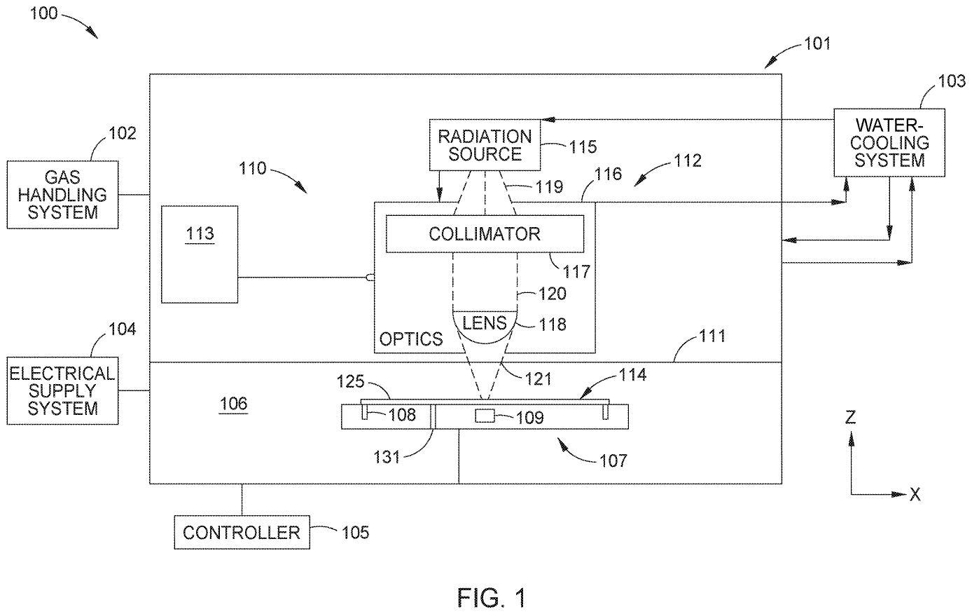

FIG. 1 is a schematic side view of a processing system 100 for thermally processing a substrate 114. Thermally processing a substrate 114 means conducting any thermal process. Exemplary embodiments of such thermal processes include thermal annealing of substrates or thermal processes used in chemical vapor deposition (CVD). Other exemplary embodiments include annealing one or more layers of a layer stack disposed atop an upper surface 125 of the substrate 114.

The substrate 114 is any suitable substrate, such as a single crystal silicon substrate, silicon on insulator (SOI), silicon germanium or alloys thereof, glass or quartz substrate with a silicon layer thereon, or other materials used for manufacturing thin film transistors (TFTs). In one or more embodiments, the substrate 114 includes a diameter from about 100 millimeters (mm) to about 1000 mm such as about 300 mm. The substrate 114 may have a layer stack (not shown) disposed on an upper surface 125 of the substrate 114. In one or more embodiments, the layers may include one or more layers of silicon dioxide (SiO₂). In one or more embodiments, the layer(s) may include varying properties such as differences in reflectivity (and inversely, absorptivity) due to, for example, differences in refractive indices and film thicknesses.

The processing system 100 includes a substrate processing chamber 101, a gas handling system 102, a water-cooling system 103, and an electrical supply system 104, and a controller 105.

In one or more embodiments, the system 100 includes a gas handling system 102 configured to supply gases to the processing volume 106 and configured to control the pressure within the processing chamber 101. In one or more embodiments, the gas handling system 102 may be capable of providing an atmosphere within the processing chamber including, but not limited to, an atmosphere of Nitrogen, Oxygen, Argon, Helium, air, or any combination thereof. In one or more embodiments, the gas handling system 102 is further configured to maintain a pressure in the processing chamber 101, for instance, maintain a vacuum or maintain a pressure above ambient pressure. In one or more embodiments, the gas handling system 102 may include a pump assembly (not shown) fluidly coupled to the processing volume 106 and/or one or more components of the processing chamber 101. In some embodiments, the pump assembly (not shown) includes one or more pumps. The one or more pumps may be configured to generate a vacuum for one or more of holding the substrate 114 to a substrate support 107 positioned in the processing chamber 101, evacuate the processing chamber 101, or may be used for other purposes.

In one or more embodiments, the system 100 includes a water cooling system 103 for supplying cooled water to various cooling systems of the processing system 100. In one or more embodiments, the water cooling system 103 may be fluidly coupled to the processing chamber 101 to control the temperature of the processing chamber 101. In one or more embodiments, the water cooling system 103 is fluidly coupled to components within the processing chamber (e.g., laser annealing apparatus 110 as further described below). In one or more embodiments, the processing system 100 includes an electrical supply system 104 configured to supply electrical power to the various components of the processing system 100.

In one or more embodiments, the processing system 100 includes a controller 105. The controller 105 may include a programmable central processing unit (CPU) which is operable with a memory (e.g., non-transitory computer readable medium and/or non-volatile memory) and support circuits. The support circuits are coupled to the CPU and includes cache, clock circuits, input/output subsystems, power supplies, the like, and combinations thereof. The support circuits may be coupled to the various components of the processing system 100, to facilitate performing one or more operations of method 400. For example, in one or more embodiments the CPU is one of any form of general purpose computer processor used in a semiconductor processing setting, such as a programmable logic controller (PLC), for controlling various substrate processing components. The memory is non-transitory and is one or more of readily available memory such as random access memory (RAM), read only memory (ROM), floppy disk drive, hard disk, or any other form of digital storage, local or remote.

Herein, the memory is in the form of a computer-readable storage media containing instructions (e.g., non-volatile memory), that when executed by the CPU, facilitates substrate processing. The instructions in the memory are in the form of a program product such as a program that implements the methods of the present disclosure (e.g., middleware application, equipment software application, etc.). The program code may conform to any one of a number of different programming languages. In one or more embodiments, the disclosure may be implemented as a program product stored on computer-readable storage media for use with a computer system. The program(s) of the program product define functions of the embodiments (including the methods and operations described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

The various methods (such as method 400) and operations disclosed herein may generally be implemented under the control of the CPU of the controller 105 by the CPU executing computer instruction code stored in the memory. When the computer instruction code is executed by the CPU, the CPU conducts operations in accordance with the various methods and operations described herein. In one or more embodiments, the memory (a non-transitory computer readable medium) includes instructions stored therein that, when executed, cause the method (such as the method 400) described herein to be conducted. The operations described herein can be stored in the memory in the form of computer readable logic.

Referring still to FIG. 1, the processing chamber 101 includes a chamber body which defines a processing volume 106 in which a substrate 114 is processed. A substrate support 107 is disposed in the processing volume 106 and supports the substrate 114 during processing. The substrate support 107 includes any platform or chuck capable of securely holding the substrate 114. In some embodiments, the substrate support 107 may include a system or assembly for grasping the substrate, such as a frictional, gravitational, mechanical, or electrical system. For instance, in some embodiments, the substrate support 107 may include mechanical clamps, electrostatic or vacuum chucks, or the like. In one or more embodiments, the substrate support 107 includes an edge ring, which may support the substrate 114 by its peripheral edge. In one or more embodiments, the substrate support 107 further includes a substrate handling mechanism 108 configured to manipulate the substrate 114 before, during, or after processing. In one or more embodiments, the substrate handling mechanism includes lift pins configured to raise or lower the substrate 114 into and/or out of a processing position. The lift pins may raise or lower the substrate 114 when the substrate 114 is transferred into or out of the processing chamber 101.

In one or more embodiments, the substrate support 107 includes a substrate support heater 109. The substrate support heater 109 is configured to control and/or maintain a temperature of the substrate 114 during processing. In one or more embodiments, the substrate support heater 109 is configured to maintain a temperature ranging from about 0° C. to about 1000° C., such as from about 100° C. to about 500° C.

In one or more embodiments, the substrate support 107 further includes one or more ports 131 fluidly coupling a backside of the substrate 114 to the gas handling system 102 (such as to one or more of the pump(s) of the aforementioned pump assembly). In one or more embodiments, the one or more ports 131 allows the substrate 114 to be chucked by the gas handling system 102 (e.g., the one or more pump(s)). In one or more embodiments, the one or more ports 131 allows for backfilling with a gas (e.g., nitrogen) to ensure thermal contact between the substrate 114 and the substrate support heater 109.

In one or more embodiments, the height of the substrate support 107 may be adjustable in the Z-direction (i.e., towards or away from the optical window 111). Adjustability in the Z-direction allows for adjustability of the position of the substrate 114 within the processing volume 106.

The processing chamber 101 further includes a laser annealing apparatus 110 disposed above the substrate support 107. In one or more embodiments, the processing chamber 101 includes a window 111 (e.g., a quartz window) disposed between the laser annealing apparatus 110 and the substrate support 107. The laser annealing apparatus 110 includes a radiation module 112 and a radiation module support system 113. The radiation module 112 includes a radiation source 115 and optics 116. The laser annealing apparatus 110 is configured to emit radiation (e.g., in the form of a laser beam) towards the substrate to heat the substrate 114. Thus, the radiation output by the laser annealing apparatus 110 may be referred to herein as either a “laser” or more broadly as “radiation.” In one or more embodiments, the radiation anneals the upper surface 125 of the substrate 114 (e.g., the layer stack). In one or more embodiments, the laser annealing apparatus 110 may be fluidly coupled to the water-cooling system 103 as previously described. The water-cooling system 103 may supply fluid (e.g., water or other aqueous mixture) to cool one or more of the components of the laser annealing apparatus 110. For instance, the water-cooling system 103 may cool the radiation module 112 and the radiation module support system 113 allowing for temperature control of the laser annealing apparatus 110 during operations.

The radiation source 115 is capable of generating radiation and exposing the substrate 114 to rapid high temperature anneal pulses. The rapid high temperature anneal pulses may be referred to as dynamic surface anneal (DSA) pulses. During operations, these pulses are applied to the upper surface 125 of the substrate 114 (e.g., the layer stack) to anneal the upper surface 125 (e.g., the layer stack) of the substrate 114.

In some embodiments, the laser annealing process may be a millisecond anneal process, which includes heating the substrate to a temperature in a range from about 800° C. to about 1,300° C., or in a range from about 1,000° C. to about 1,300° C., or in a range from about 1,000° C. to about 1,200° C., or about 1,150° C. to about 1,200° C. In some embodiments, the millisecond anneal process may include heating the substrate for a period of about 0.05 milliseconds to about 5 milliseconds, about 0.1 milliseconds to about 2 milliseconds, about 0.2 millisecond to about 1 millisecond, or about 0.5 millisecond to about 1 millisecond.

Furthermore, as the radiation may be absorbed at or near the upper surface 125 of the substrate 114 (e.g., the layer stack). The radiation may have a wavelength within the range at which the upper surface 125 of the substrate (e.g., the layer stack) absorbs radiation. In some embodiments, the radiation has a wavelength in a range from about 750 nanometers (nm) to about 3000 nm, such as from about 800 nm to about 1200 nm, such as about 1000 nm to about 1100 nm, such as about 1070 nm. Wavelengths produced by such radiation laser sources are strongly absorbed by most otherwise reflective materials.

In one or more embodiments, the radiation output by the laser annealing apparatus 110 is p-polarized light in that the radiation is polarized in the plane of incidence. Without being limited to this or any other theory, the plane of incidence may comprise the plane including the ray of the laser output from the annealing apparatus 110 and the rays of reflected radiation reflected off of the upper surface 125 and the surface normal extending outward from the upper surface 125 of the substrate 114.

The radiation source 115 may comprise multiple laser diode(s), each of which produces uniform and spatially coherent light at the same wavelength. The power of the laser diode(s) is in the range from about 0.1 kilowatts (kW) to about 5 kW, such as from about 1 kW to about 3 kW, such as about 1.5 kW to about 2.5 kW.

The optics 116 may be positioned between the radiation source 115 and the substrate support 107. The optics 116 may include one or more collimators 117 and at least one lens 118.

The one or more collimators 117 collimate the radiation 119 from the radiation source 115 into a substantially parallel collimated beam. This collimated radiation 120 is then focused by the at least one lens 118 into a beam of radiation 121 directed to the upper surface 125 of the substrate 114. The at least one lens 118 is any suitable lens, or series of lenses, capable of focusing the collimated radiation 120 into a radiation beam 121. In some embodiments, the lens 118 is a cylindrical lens. In other embodiments, the lens 118 may be one or more concave lenses, convex lenses, plane mirrors, concave mirrors, convex mirrors, refractive lenses, diffractive lenses, Fresnel lenses, gradient index lenses, or the like. In one or more embodiments, the optics 116 may further include other components including, but not limited to, pyrometer(s), reflectometer(s), refractive beam transformer(s), and diffractive optics.

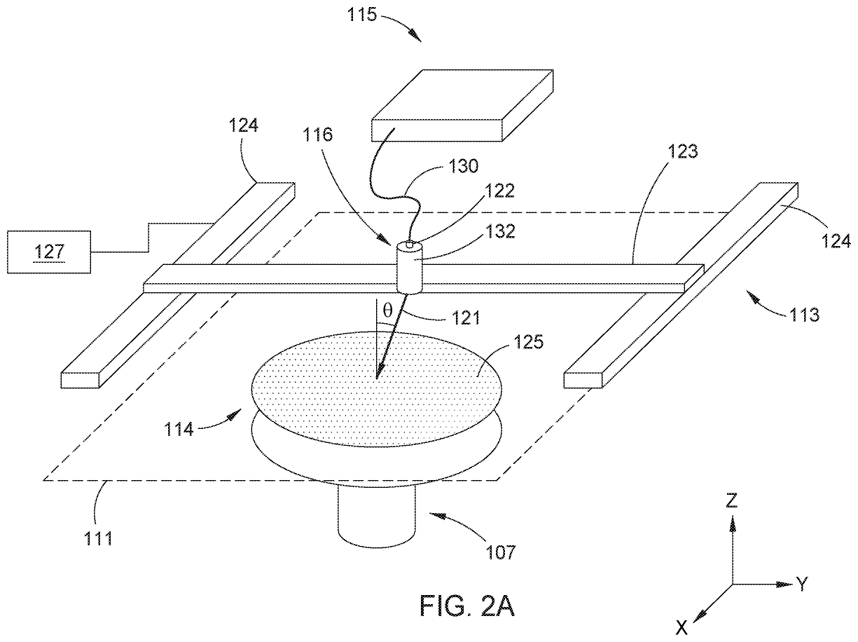

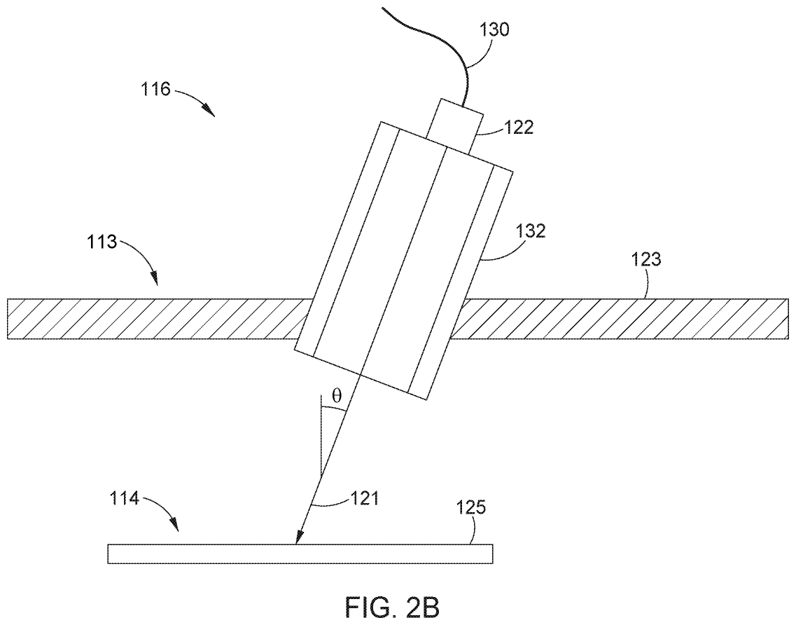

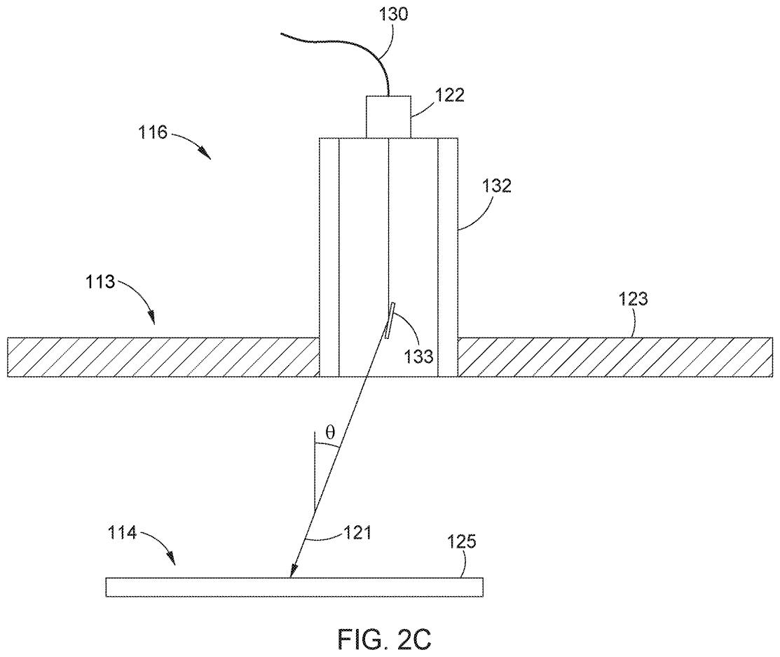

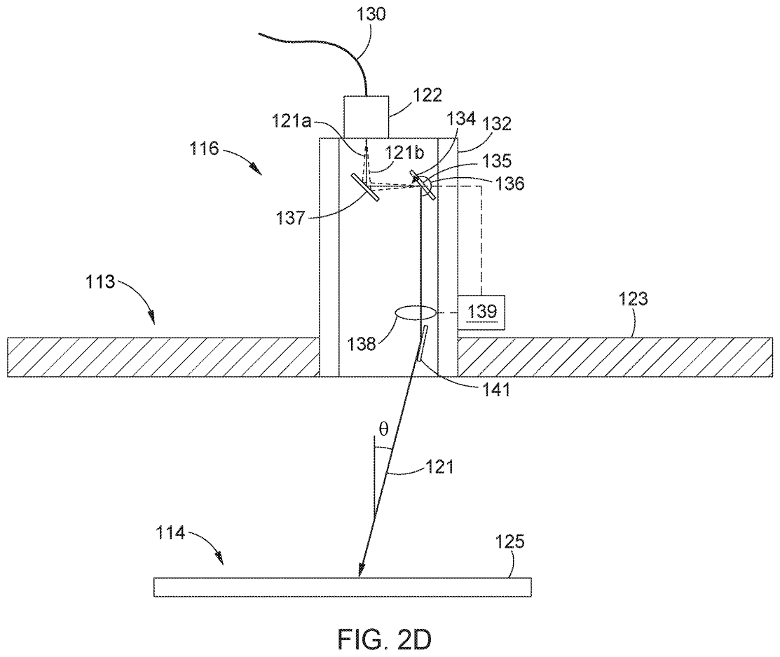

A radiation module support system 113 may support the radiation source 115 and/or the optics 116 within the processing chamber 101. FIG. 2A illustrates a schematic isometric view of the laser annealing apparatus 110 and provides a more detailed view of the radiation module support system 113 according to some embodiments.

For instance, in some embodiments, the radiation module support system 113 positions and translates one or more portions of the laser annealing apparatus 110 so as to traverse the radiation beam 121 across the upper surface 125 of the substrate 114 during operations. Specifically, the radiation module support system 113 may support a radiation emitting end portion 122 (or more simply “end portion 122”) which may include or house one or more components of the optics 116 schematically illustrated in FIG. 1. A suitable connector 130 may couple the end portion 122 (or one or more components positioned therein) to the remainder of the radiation module 112 (e.g., radiation source 115). In some embodiments, the connector 130 may comprise a fiber optic cable. In one or more embodiments, the end portion 122 is coupled (e.g., optically coupled) to an optical column 132. The optical column 132 is configured to shape the incoming beam from the end portion 122 into a desired irradiance profile. In one or more embodiments, the optical column 132 may include refractive and reflective elements that serve to generate the desired irradiance profile which may include one or more components of the optics 116 illustrated in FIG. 1 and described therewith.

In one or more embodiments, the radiation module support system 113 (or more simply “support system 113”) is further configured to translate the radiation emitting portion of the radiation source 115 and optics 116 such that the beam of radiation 121 is translated about the X-Y plane to traverse (e.g., “scan”) the entirety of the upper surface 125 of the substrate 114. In one or more embodiments, the substrate support 107 is configured to move rather than the support system 113 to cause the beam of radiation 121 to translate about the X-Y plane to traverse the entirety of the upper surface 125 of the substrate 114. In one or more embodiments, both the substrate support 107 and the support system 113 are configured to move to cause the beam of radiation 121 to translate about the X-Y plane to traverse the entirety of the upper surface 125 of the substrate 114. In one or more embodiments, the radiation support system 113 is a gantry system including one or more elongate first cross-members 123 (or “first cross-member(s)” 123) and one or more elongate second cross-members 124 (or “second cross-member(s) 124). The first cross-member(s) 123 may extend along a first direction, and the second cross-member(s) 124 may extend along a second direction that is perpendicular to the first direction. In the illustration provided in FIG. 2, the first direction of the first cross-member(s) 123 may be parallel to the Y axis and the second direction of the second cross-member(s) 124 may be parallel to the X axis.

The support system 113 may also include an actuation assembly 127 that is configured to drive the end portion 122 and/or the optical column 132 along the cross-members 123, 124 to scan the laser beam 121 across the entirety (or a subset of) of the upper surface 125 of the substrate 114. The support system 113 may be communicatively coupled to the controller 105 (FIG. 1) such that the controller 105 can control the speed and path in which the support system 113 translates the laser beam 121 across the upper surface 125 during operations.

The end portion 122 and/or the optical column 132 may be mounted to the support system 113, such as to one of the first cross-members 123, so that the radiation beam 121 is directed toward the upper surface 125 of substrate 114 at an incidence angle Θ. The incidence angle Θ is an angle from or relative to a vertical axis (e.g., the Z-axis or the axis normal to the upper surface 125 of the substrate 114) at which the beam of radiation 121 is directed towards the substrate 114. In one or more embodiments, the incidence angle Θ is greater than 0° and less than about 90°, such as in a range from about 15° to about 75°, such as in a range from about 30° to about 75°, such as in a range from about 40° to about 60°, such as in a range from about 50° to about 60°, or such as about 55°.

Without being limited by theory, the incidence angle Θ may be equal to, correspond with, approximate, or be within a range of the Brewster angle of silicon dioxide (SiO₂). As used herein, the Brewster angle refers to the angle of incidence at which light with a particular polarization is perfectly transmitted through the surface of a given transparent dielectric material, with no reflection. It has been determined that orienting the radiation beam 121 along an incidence angle that is equal to or that is within a desired range of the Brewster angle for SiO₂ (e.g., such as is described for the incidence angle Θ) allows the reflectivity of the various materials and layers that may be present on (or under) the upper surface 125 of the substrate 114 to generally converge. Accordingly, a consistent temperature increase may be achieved across the surface of the substrate 114 during the laser annealing process. For example, the upper surface 125 of the substrate 114 (e.g., the layer stack) may include silicon dioxide (SiO₂). Without being limited by theory, orienting the radiation beam 121 along the Brewster angle of silicon dioxide (SiO₂) (or within a desired range thereof) allows the reflectivity to generally converge. Accordingly, a consistent temperature increase may be achieved across the surface of the substrate 114 during the laser annealing process.

As a result of orientation of the beam of radiation 121 along the incidence angle Θ, the beam of radiation 121 may transmit through the upper surface 125 of the substrate 114 (e.g., the top layer of the layer stack) without reflection losses (or with minimal reflection losses). Further, without being limited by theory, as the beam of radiation 121 is transmitted through the upper surface 125 of the substrate 114 (e.g., the top layer of the layer stack), the incidence angle Θ also permits the beam of radiation 121 to transmit through the subsequent layers with minimized reflection. For instance, in some embodiments, the percentage of the beam of radiation 121 that is reflected during a laser annealing operation by use of the laser annealing apparatus 110 may be in a range from about 0% to about 20%, such as from about 10% to about 15%, or such as about 12%.

FIG. 2A illustrates a schematic side cross-sectional view of the end portion 122 and the optical column 132, according to one or more embodiments.

In one or more embodiments, the end portion 122 and/or the optical column 132 may be canted such that the beam of radiation 121 is emitted from the end portion 122 and through the optical column 132 at the angle of incidence Θ. In one or more embodiments, the end portion 122 and the optical column 132 are rigidly coupled to the support system 113 (e.g., the first cross-member(s)” 123) to achieve the desired angle of incidence Θ. In one or more embodiments, the end portion 122 and the optical column 132 are movably mounted (e.g., by a mechanism such as a motor) to the support system 113 (e.g., the first cross-member(s) 123) such that the angle of incidence Θ can be adjusted. The adjustment may be through a feedback loop (e.g., the angle of incidence Θ can be measured and the angle of the optical column 132 and/or the end portion 122 can be changed.

FIG. 2B illustrates a schematic side cross-sectional view of the end portion 122 and the optical column 132, according to one or more embodiments.

In one or more embodiments, the end portion 122 and/or the optical column 132 are oriented at an angle different from the desired angle of incidence Θ. In one or more embodiments, such as the illustrated embodiment, the end portion 122 and/or the optical column 132 are oriented vertically (e.g., substantially vertically). In one or more of such embodiments, the optical column 132 may include one or more mirrors 133 or mechanisms to redirect the beam emitted by the end portion 122. The one or more mirrors 133 adjust the angle of the beam 121 within the optical column 132 to achieve the angle of incidence Θ. That is, the end portion 122 may emit the beam 121 in a particular orientation (e.g., vertically, substantially vertically, or some other orientation which may or may not be the angle of incidence Θ) and the one or more mirrors 133 are configured to (e.g., oriented to) redirect the beam 121 to achieve the angle of incidence Θ such that the beam 121 leaves the optical column 132 and is directed towards the substrate 114 at the angle of incidence Θ. In one or more embodiments, the one or more mirrors 133 may be movable such that the angle of the beam 121 is movable. Although illustrated as one mirror 133, there may be more than one mirror 133 such as two, three, four, five, or more mirrors 133 configured to redirect the beam 121 such that the beam 121 is at the angle of incidence Θ when it leaves the optical column 132 towards the substrate 114. In one or more embodiments, the one or more mirrors 133 may also be outside of the optical column 132 and/or a separate component from the optical column 132. The embodiment illustrated in FIG. 2C including the one or more mirrors 133 may also be utilized with the embodiment illustrated in FIG. 2B (e.g., when the optical column 132 and/or the end portion 122 are canted and are rigidly or are movably coupled to the support system 113).

FIG. 2C illustrates a schematic side cross-sectional view of the end portion 122 and the optical column 132, according to one or more embodiments. In one or more embodiments, the optical column 132 includes a fast steering mirror (“FSM”) 134. The FSM 134 is a movable mirror (e.g., pivotable mirror) that may be used to actively adjust the beam 121 emitted from the end portion 122 to adjust the angle of incidence Θ. In one or more embodiments, the FSM 134 is controlled by a feedback loop to adjust the angle of the beam 121 to achieve the desired angle of incidence Θ.

This becomes particularly important when the beam 121 emitted by the end portion 122 has a variable angle. Without being bound by theory the angle of the beam 121 emitted by the end portion 122 may have slight variation due to numerous factors. Said variation may cause the beam 121 emitted by the end portion 122 to have a varying angle (e.g., the angle of the beam 121 emitted by the end portion 122 may move or may constantly move). Without being bound by theory, the variation may be due to coupling of radiation source 115 to the connector 130, the coupling of the connector 130 to the end portion 122, may be due to the coupling of the end portion 122 to the optical column 132, or may be due to internal variability within one or more of the radiation source 115, the connector 130, and the end portion 122. This variability can be corrected by the FSM 134. The FSM 134 may be movable to adjust the angle of the beam 121 emitted by the end portion 122 to achieve the angle of incidence Θ. In one or more embodiments, such as the illustrated embodiment, the FSM 134 is pivotable about a pivot point 135 (as illustrated by arrow 136) to achieve the angle of incidence Θ (e.g., correct for a difference between the angle at which the beam 121 is emitted and angle of incidence Θ). In one or more embodiments, the FSM 134 is operated by a motor (not illustrated) to move (e.g., pivot) the FSM 134 to achieve the angle of incidence Θ.

In one or more embodiments, the optical column 132 includes a mirror 137 (e.g., a fixed mirror or movable mirror), the FSM 134, and a beam sensor 138 (e.g., detector). The FSM 134 and the beam sensor 138 may be communicably coupled to a controller 139 (the controller 139 may be controller 105 of FIG. 1 or may be a separate controller which may or may not be coupled to controller 105 of FIG. 1). In one or more embodiments, the detector 138, may be an in-line detector, as illustrated. In one or more embodiments, detector 138 may be a mirror or other refractive or reflective component configured to reflect a small amount of light from beam 121 (e.g., less than 5% of the light, such as 1% of the light or less) into a detector (e.g., a detector distinct from the refractive and/or reflective component) which may be positioned to receive the reflected light to measure the angular position of the beam 121. The controller 139 may utilize information sensed by the beam sensor 138 (and received from the beam sensor 138) to control the FSM 134. According to one or more modes of operation, the beam 121 emitted from the end portion 122 is directed towards the mirror 137, the mirror 137 redirects the beam 121 to the FSM 134, the FSM 134 redirects the beam 121 through the beam sensor 138 and out of the optical column 132 at the angle of incidence Θ. Without being bound by theory, the beam 121 emitted by the end portion 122 may have variability, illustrated as beam 121a and beam 121b (in dashed lines). Beams 121a and 121b are included for illustrative purposes only to indicate the variability of the beam 121 and illustrate how the FMS 134 is utilized to correct for this variability. These beams 121a and 121b are directed to the mirror 137 which redirect the beams 121a, 121b towards the FSM 134. The FSM 134 redirects the beams 121a, 121b through the beam sensor 138 and out of the optical column 132 at the angle of incidence Θ. The adjustability (e.g., rotatability) of the FSM 134 allows for the FSM 134 (through the controller 139) to account for the variation in beam angle illustrated by beams 121a, 121b. That is, as the beams 121a, 121b are redirected through the beam sensor 138, the beam sensor 138 is configured to measure the angle at which these beams 121a, 121b are directed. The controller 139 is configured to receive these angle measurements from the beam sensor 138 and adjust (e.g., control the orientation of) the FSM 134 accordingly. Thus, if the controller 139 determines that the beam 121 (e.g., beam 121a, 121b) is not at the angle of incidence Θ when it leaves the optical column 132, the controller 139 is configured to orient the FSM 134 to correct for the variability in the beam 121 (e.g., beam 121a, 121b). That is, the FSM 134 and the beam sensor 138 operate in a feedback loop such that there is active correction/adjustment of the angle of the beam 121 to achieve the angle of incidence Θ.

In one or more embodiments, such as the illustrated embodiment, the optical column 132 further includes one or more additional mirrors 141 (e.g., a fixed mirror or movable mirror). In one or more of such embodiments, such as the illustrated embodiment, the one or more additional mirrors 141 are downstream of the beam sensor 138 (e.g., optically following the beam sensor 138). In one or more of such embodiments, the beam 121 may pass through the beam sensor 138 at an angle that is different from the desired angle of incidence Θ and the one or more additional mirrors 141 redirect the beam 121 to the desired angle of incidence Θ. Accordingly, in one or more of such embodiments, the beam sensor 138 is comparing the measured angle to an angle that is different from the desired angle of incidence Θ but is correlated to the desired angle of incidence Θ due to a known angle at which the one or more additional mirrors will redirect the beam 121 (e.g., as illustrated, the beam sensor 138 may be configured to determine whether or not the beam 121 leaving the FSM 134 is vertical, or substantially vertical, because the one or more additional mirrors 141 are configured to, or angled to, redirect a beam 121 that is vertical, or substantially vertical, to the desired angle of incidence Θ). Accordingly, through use of the beam sensor 138, the controller 139 can adjust the angle of the FSM 134 to achieve the desired input angle to the one or more additional mirrors 141 (e.g., as shown in FIG. 2D, the controller 139 may correct the FSM 134 such that the beam 121 will pass through the beam sensor 138 vertically, or substantially vertically, because the one or more additional mirrors will redirect the beam 121 to be at the desired angle of incidence Θ when the beam 121 that hits the one or more additional mirrors 137 vertically, or substantially vertically). In one or more embodiments, the one or more additional mirrors 141 may be inside or outside of the optical column 132.

In one or more embodiments, while not shown, it is contemplated that the one or more additional mirrors 141 may be upstream of the beam sensor 138. In one or more of such embodiments, the control system operates similarly to how the embodiment without one or more additional mirrors 141 operates. That is, the beam 121 leaves the FSM 134 which may or may not be at the desired angle of incidence Θ, the beam 121 reflects off of the one or more additional mirrors 141 upstream of the beam sensor 138, the beam sensor 138 measures the angle of the beam 138, and the controller 139 compares that measurement to the desired angle of incidence Θ and corrects the orientation of the FSM 134 accordingly.

According to one or more modes of operation, such as the mode of operation illustrated in FIG. 2D, the end portion 122 emits the beam 121, the beam 121 is redirected by the mirror 137 towards the FSM 134, the FSM 134 redirects the beam 121 through the beam sensor 138, and the one or more additional mirrors 141 redirects the beam 121 out of the optical column 132. Simultaneously (or substantially simultaneously), the beam sensor 138 is measuring the angle at which the beam 121 is directed (e.g., the angle at which the beam 121 is leaving the optical column 132), the controller 132 receives this measurement and compares the measured angle with an angle correlated to the desired angle of incidence Θ (e.g., the angle that would result in the one or more additional mirrors 141 redirecting the beam 121 to the angle of incidence Θ), if it is determined (e.g., if the controller 139 determines) that the measured angle differs from the desired angle, the controller 139 is configured to adjust the FSM 134 (e.g., the orientation of the FSM 134) to adjust for the difference between the measured angle and the desired angle needed to ultimately achieve the desired angle of incidence Θ at the top surface 125 of the substrate 114, thus providing an active feedback loop. The adjustments may be made discretely (e.g., in certain intervals or at certain points in time) or continuously throughout the operation. The controller 139, the beam sensor 138, and the FSM 134 may also be used to make one time (or multiple time) adjustments to the angle of the beam 121, for instance, if a new angle of incidence Θ is desired based on the operation being conducted. In one or more embodiments one or more of the mirror 137, the FSM 134, and/or the beam sensor 138 may be inside (as illustrated) or outside of the optical column 132 (such as part of a separate component). In one or more embodiments, the FSM 134 and the beam sensor 138 may operate in a similar fashion without the mirror 137.

The embodiment illustrated in FIG. 2D including the FSM 134 may also be utilized with the embodiment illustrated in FIG. 2B (e.g., when the optical column 132 and/or the end portion 122 are canted and are rigidly or are movably coupled to the support system 113) and/or may be utilized with the embodiment illustrated in FIG. 2C (e.g., when the optical column 132 includes mirror 133 and the optical column 132 and/or the end portion 122 are oriented at an angle, such as vertical or substantially vertical, which may or may not be different from the angle of incidence Θ). In one or more of such embodiments, the mirror(s) 133 may be downstream of the beam sensor 138 (e.g., optically closer to the substrate 114 as compared to the beam sensor 138) or may be upstream of the beam sensor 138 (e.g., optically further from the substrate 114 as compared to the beam sensor 138).

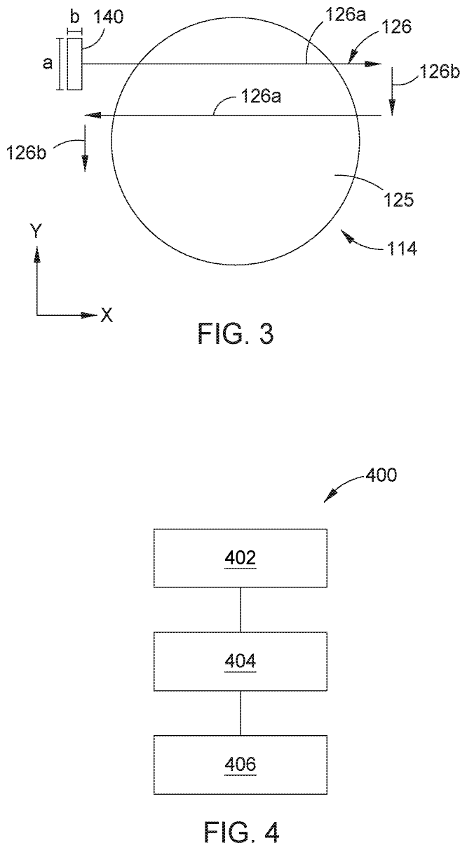

The path 126 of the radiation beam 121 and cross-section 140 of the radiation beam 121 are shown in FIG. 3 according to some embodiments. Specifically, FIG. 3 is a schematic top view of the substrate 114 during thermal processing.

As shown in FIG. 3, the support system 113 may translate the end portion 122 and/or the optical column 132 such that the radiation beam 121 traverses (e.g. “scans”) the upper surface 125 of the substrate 114 along a pre-determined path 126. In one or more embodiments, the path 126 may be a so-called raster path that includes a plurality of passes or movements in a first direction 126a (which may be aligned with or parallel to the X-direction interleaved with a plurality of passes or movements in a second direction 126b (which may be aligned with or parallel to the Y-direction). As shown, the movements in the first and second direction 126a, 126b may allow the radiation beam 121 to traverse back and forth across the upper surface of the substrate 114 during operations.

In one or more embodiments, the radiation module support system 113 translates the cross-section 140 faster in the first direction 126a than it does in the second direction 126b. For instance, in one or more embodiments, the radiation module support system 113 may translate the cross-section 140 at more than 300 mm/s in the fast direction 126a. Thus, first direction 126a and second direction may sometimes be referred to as the “fast direction” and “slow direction,” respectively.

As is also shown in FIG. 3, the radiation beam 121 may also have a particular cross-section 140 as projected onto the upper surface 125 of the substrate. In some embodiments, the cross-section 140 of the radiation beam 121 may be at least partially dictated by the radiation source 115, the position and orientation of radiation source 115, the optics 116, the position and orientation of optics 116, and/or the angle Θ (among other factors). In some embodiments, the cross-section 140 may be the cross-section of the radiation beam 121 taken along a plane or direction that is aligned with or parallel to the X-Y plane (FIGS. 2 and 3) or the upper surface 125 of substrate 114. In one or more embodiments, the cross-section 140 may be rectangular in shape and includes a length a aligned with the slow direction 126b (and thus also the Y-direction), and a width b aligned with the fast direction 126a (and thus also the X-direction). In one or more embodiments, length a may be in a range of from about 0.1 mm to about 300 mm, such as greater or equal to about 10 mm, or such as about 13.5 mm. In one or more embodiments, the width b may be less than 1 mm, such as less than about 100 micrometers (um), or such as less than about 80 μm.

In one or more embodiments, the cross-section 140 of the radiation beam 121 may have a top-hat profile in slow direction 126b (illustrated as the Y-direction) and may have a symmetric Gaussian-like profile in the fast direction 126a (illustrated as the X-direction).

FIG. 4 illustrates a method 400 for processing a substrate (such as substrate 114 of FIGS. 1-3). At operation 402, the substrate is positioned within a processing chamber (such as processing chamber 101 of FIG. 1). In one or more embodiments, the substrate includes a layer stack disposed on an upper surface of the substrate. In one or more embodiments, at least one of the layers of the layer stack includes a layer including SiO₂.

At operation 404, the substrate is exposed to a beam of radiation (such as radiation beam 121). In one or more embodiments, the beam of radiation is generated by a radiation source (such as radiation source 115) and focused via optical components (such as optics 116). In one or more embodiments, the beam of radiation has a wavelength in a range from about 750 nm to about 3000 nm, such as from about 800 nm to about 1200 nm, such as about 1000 nm to about 1100 nm, such as about 1070 nm. Wavelengths produced by such radiation laser sources are strongly absorbed by most otherwise reflective materials. In one or more embodiments, the radiation is p-polarized light. In one or more embodiments, the beam of radiation is generated using multiple laser diode(s), each of which produces uniform and spatially coherent light at the same wavelength with a power in the range from about 0.1 kW to about 5 kW, such as from about 1 kW to about 3 kW, such as about 1.5 kW to about 2.5 kW.

In one or more embodiments, the beam is emitted at an incidence angle (such as angle Θ). In some embodiments, the incidence angle may be the same as the incidence angle Θ previously described. In one or more embodiments, the beam is subject to optical components (e.g., refractive components) to direct the beam at the angle of incidence Θ such as those previously described (e.g., those described with respect to FIGS. 1-2D). In one or more embodiments, the angle of the beam may be controlled (e.g., actively controlled) by optical components (e.g., refractive components) similar to those described with respect to FIG. 2D).

In one or more embodiments, the beam includes a cross-section (such as cross-section 140) with a length (such as length a) from about 0.1 mm to about 300 mm, such as greater than 10 mm, such as about 13.5 mm. In one or more embodiments, the cross-section may include a width (such as width b) less than 1 mm, such as less than 100 um, such as less than 80 um. In one or more embodiments, the length may have a top-hat profile and the width may have a symmetric Gaussian-like profile.

At operation 406, the beam is translated across (i.e., scan) the upper surface of the substrate thereby heating (and annealing) at least a portion of the upper surface (and/or the layer stack disposed thereon). In one or more embodiments, the beam is translated by one or more of a radiation module support system (such as support system 113) and the substrate support. In one or more embodiments the beam is translated by the radiation module support system. In one or more embodiments, the substrate support moves the substrate thus causing the beam to translate. In one or more embodiments, both the radiation module support system and the substrate support move to translate the beam. The radiation module support system may include a gantry system. One or more of the radiation module support system and the substrate support move the beam in a path (such as path 126) making a complete pass of the diameter of the substrate in a first direction (illustrated as the X-direction in FIG. 3) and incrementally moving in a second direction (illustrated as the Y-direction in FIG. 3). In one or more embodiments, the one or more of the radiation module support system and the substrate support move the beam faster in the first direction than it does in the second direction. In one or more embodiments, the one or more of the radiation module support system and the substrate support move the beam 300 mm/s in the first direction. In one or more embodiments, the first direction is the same direction as the width of the cross-section of the beam and the second direction is the same direction as the length of the cross-section of the beam.

The preceding discussion is directed to various embodiments. However, one of ordinary skill in the art will understand that the examples disclosed herein have broad application, and that the discussion of any embodiment is meant only to be exemplary of that embodiment, and not intended to suggest that the scope of the disclosure, including the claims, is limited to that embodiment.

The drawing figures are not necessarily to scale. Certain features and components herein may be shown exaggerated in scale or in somewhat schematic form and some details of conventional elements may not be shown in interest of clarity and conciseness.

In the preceding discussion and in the claims, the terms “including” and “comprising” are used in an open-ended fashion, and thus should be interpreted to mean “including, but not limited to . . . .” Also, the term “couple” or “couples” is intended to mean either an indirect or direct connection. Thus, if a first device couples to a second device, that connection may be through a direct connection of the two devices, or through an indirect connection that is established via other devices, components, nodes, and connections. In addition, as used herein, the terms “axial” and “axially” generally mean along or parallel to a given axis (e.g., central axis of a body or a port), while the terms “radial” and “radially” generally mean perpendicular to the given axis. For instance, an axial distance refers to a distance measured along or parallel to the axis, and a radial distance means a distance measured perpendicular to the axis. Further, when used herein (including in the claims), the words “about,” “generally,” “substantially,” “approximately,” and the like, when used to refer to a stated value, mean within a range of plus or minus 10% of the stated value.

When introducing elements of the present disclosure or exemplary aspects or embodiments thereof, the articles “a,” “an,” “the” and “said” are intended to mean that there are one or more of the elements.

The terms “comprising,” “including” and “having” are intended to be inclusive and mean that there may be additional elements other than the listed elements.

While exemplary embodiments have been shown and described, modifications thereof can be made by one skilled in the art without departing from the scope or teachings herein. The embodiments described herein are exemplary only and are not limiting. Many variations and modifications of the systems, apparatus, and processes described herein are possible and are within the scope of the disclosure. Accordingly, the scope of protection is not limited to the embodiments described herein, but is only limited by the claims that follow, the scope of which shall include all equivalents of the subject matter of the claims. Unless expressly stated otherwise, the steps in a method claim may be performed in any order. The recitation of identifiers such as (a), (b), (c) or (1), (2), (3) before steps in a method claim are not intended to and do not specify a particular order to the steps, but rather are used to simplify subsequent reference to such steps.

What is claimed is:

1. A substrate processing chamber comprising:
a substrate support disposed in a processing volume of the substrate processing chamber;
a radiation module configured to generate and emit a beam of radiation including a wavelength within a range of about 750 nanometers (nm) to about 3000 nm; and
a support system configured to:
support a radiation emitting end portion of the radiation module such that the beam of radiation is emitted at an incidence angle towards the substrate support, wherein the incidence angle of incidence is in a range of about 15° to about 70° from a vertical axis; and
move the radiation emitting end portion to scan an upper surface of a substrate with the beam of radiation; and
a window positioned between the radiation module and the substrate support.

2. The substrate processing chamber of claim 1, wherein the incidence angle is in a range of about 50° to about 60° from the vertical axis.

3. The substrate processing chamber of claim 1, wherein the wavelength is within a range of about 1000 nm to about 1100 nm.

4. The substrate processing chamber of claim 1, wherein the support system is a gantry system including a first cross-member in a first direction and a second cross-member in a second direction that is perpendicular to the first direction.

5. The substrate processing chamber of claim 4, wherein the support system includes an actuation assembly configured to drive the radiation emitting end portion along the first cross-member and the second cross-member.

6. The substrate processing chamber of claim 5, wherein the actuation assembly is configured to drive the radiation emitting end portion faster in the first direction than it is in the second direction.

7. The substrate processing chamber of claim 1, wherein the beam of radiation is p-polarized.

8. The substrate processing chamber of claim 1, wherein the radiation module includes laser diodes configured to generate the beam of radiation, wherein the laser diodes include a power in the range of about 1.5 kilowatts (kW) to about 2.5 kW.

9. The substrate processing chamber of claim 1, wherein the radiation emitting end portion is coupled to a remainder of the radiation module by a fiber optic cable.

10. A laser annealing system for annealing a substrate, comprising:
a radiation module configured to generate and emit a beam of radiation towards the substrate, the beam of radiation including a wavelength within a range of about 750 nanometers (nm) to about 3000 nm; and
a support system configured to:
support a radiation emitting end portion of the radiation module such that the beam of radiation is emitted at an incidence angle that is in a range of about 15° to about 70° from a vertical axis; and
move the radiation emitting end portion to scan an upper surface of the substrate with the beam of radiation.

11. The laser annealing system of claim 10, wherein the incidence angle is in a range of about 50° to about 60° from the vertical axis.

12. The laser annealing system of claim 10, wherein the wavelength is within a range of about 1000 nm to about 1100 nm.

13. The laser annealing system of claim 12, wherein the support system is a gantry system including a first cross-member in a first direction and a second cross-member in a second direction that is perpendicular to the first direction.

14. The laser annealing system of claim 13, wherein the support system includes an actuation assembly configured to drive the radiation emitting end portion along the first cross-member and the second cross-member.

15. The laser annealing system of claim 14, wherein the actuation assembly is configured to drive the radiation emitting end portion faster in the first direction than it is in the second direction.

16. A method of annealing a substrate, the method comprising:
exposing the substrate to a beam of radiation generated by a radiation module, wherein the substrate is disposed on a substrate support and the beam of radiation includes:
a wavelength within a range of about 750 nanometers (nm) to about 3000 nm; and
an incidence angle that is in a range of about 15° to about 70° from a vertical axis; and
moving one or more of the radiation module and the substrate support to cause the beam of radiation to traverse an upper surface of a substrate in a path to anneal the upper surface of the substrate.

17. The method of claim 16, wherein the beam of radiation includes a rectangular cross-section as projected onto the upper surface of the substrate, and wherein the rectangular cross-section has a length greater than about 10 millimeters (mm) and a width less than about 100 micrometers (um).

18. The method of claim 16, wherein the path is a raster path including a first direction and a second direction that is perpendicular to the first direction, and wherein the radiation module is moved faster in the first direction than it is in the second direction.

19. The method of claim 16, wherein the incidence angle is in a range of about 50° to about 60° from the vertical axis.

20. The method of claim 16, wherein the wavelength is within a range of about 1000 nm to about 1100 nm.
